(19) United States
(12) Patent Application Publication
(10) Pub. No.: US 2026/0075869 A1
(43) Pub. Date: Mar. 12, 2026

(54) SEMICONDUCTOR DEVICE

(71) Applicant: NATIONAL SUN YAT-SEN UNIVERSITY, Kaohsiung (TW)

(72) Inventor: Jyi-Tsong LIN, KAOHSIUNG (TW)

(21) Appl. No.: 18/988,771

(22) Filed: Dec. 19, 2024

(30) Foreign Application Priority Data
Sep. 12, 2024 (TW) 113134669

(51) Int. Cl. H10D 30/63; H10D 64/23; H10D 86/00; H10D 86/01

(52) U.S. Cl. CPC H10D 30/637; H10D 64/258; H10D 86/01; H10D 86/201

(57) ABSTRACT

A semiconductor device includes a substrate, a semiconductor layer, a source electrode, a drain electrode and a gate electrode. The semiconductor layer is disposed on the substrate. The source electrode is in direct contact with the semiconductor layer. The drain electrode is in direct contact with the semiconductor layer. The gate electrode is between the source electrode and the drain electrode, in which the gate electrode is in direct contact with the semiconductor layer.

### CROSS-REFERENCE TO RELATED APPLICATION

This application claims priority to Taiwan Application Serial Number 113134669, filed Sep. 12, 2024, which is herein incorporated by reference in its entirety.

### BACKGROUND

### Field of Invention

The present invention relates to a semiconductor device.

### Description of Related Art

The traditional metal semiconductor field effect transistor (MESFETs) are widely used in radio frequency (RF) and microwave applications, but the traditional MESFETs still faces various challenges in the applications, such as applications for a submillimeter-wave and applications for a terahertz radiation. MESFETs with broad band materials are high-profile due to the properties of the high temperature stability and low loss at high frequencies in recent years.

However, the MESFETs with broad band materials still may not solve the issue which the electron and hole mobilities of the n type MES (nMES) and the p type MES (pMES) in the complementary metal semiconductor (CMES) are mismatched, in turn the performance of the CMES may not be enhanced. Furthermore, as the hole mobility of the pMES is much less than the electron mobility of the nMES, the CMES requires enlarging component widths in pMES, which in turn requires larger wiring and higher process costs. Therefore, how to provide a kind of MES that can solve the above issues is still a goal of the people in this field.

### SUMMARY

According to some embodiments of the present disclosure, a semiconductor device is provided. The semiconductor device may be a signal carrier device without doping by designing the semiconductor device as punch-through nMES (PTnMES) and designing source and drain electrodes of the semiconductor device as Schottky contacts. Furthermore, by adjusting the Schottky barrier between the source and drain electrodes, the semiconductor device may have current properties similar to those of the pMES without increasing the size. By matching the carrier mobilities of the nMES and the PTnMES, the semiconductor device may have great carrier mobility, thus increasing the performance of the CMES. Therefore, the semiconductor device may have great reliability and stability in applications for the RF and the microwave circuit.

According to some embodiments of the present disclosure, a semiconductor device is provided. The semiconductor device includes a substrate, a semiconductor layer, a source electrode, a drain electrode and a gate electrode. The semiconductor layer is disposed on the substrate. The source electrode is in direct contact with the semiconductor layer. The drain electrode is in direct contact with the semiconductor layer. The gate electrode is between the source electrode and the drain electrode, in which the gate electrode is in direct contact with the semiconductor layer.

According to some embodiments of the present disclosure, in which the gate electrode and the semiconductor layer form a Schottky contact.

According to some embodiments of the present disclosure, in which a Schottky barrier height between the gate electrode and the semiconductor layer is less than a Schottky barrier height between the source electrode and the semiconductor layer and a Schottky barrier height between the drain electrode and the semiconductor layer.

According to some embodiments of the present disclosure, the semiconductor device further includes a first semiconductor region, a second semiconductor region and a third semiconductor region. The first semiconductor region is adjacent to the source electrode. The second semiconductor region is adjacent to the drain electrode. The third semiconductor region is between the first semiconductor region and the second semiconductor region, in which doping concentrations of the first and second semiconductor regions are higher than a doping concentration of the third semiconductor region.

According to some embodiments of the present disclosure, in which the first semiconductor region and the second semiconductor region have a same conductive type.

According to some embodiments of the present disclosure, in which the gate electrode overlaps the third semiconductor region along a direction perpendicular to a surface of the gate electrode.

According to some embodiments of the present disclosure, the semiconductor device further includes a spacer layer. The spacer layer separates the source electrode or the drain electrode from the semiconductor layer, in which the spacer layer includes a nanoparticle, a semiconductor oxide or a nitride.

According to some embodiments of the present disclosure, the semiconductor device further includes a dielectric buffer layer. The dielectric buffer layer is between the semiconductor layer and the gate electrode, in which the dielectric buffer layer includes a nanoparticle, a semiconductor oxide or a nitride.

According to some embodiments of the present disclosure, in which the gate electrode, the source electrode and the drain electrode have the same material.

According to some embodiments of the present disclosure, in which a material of the gate electrode is different from a material of the source electrode and a material of the drain electrode.

According to some embodiments of the present disclosure, in which the source electrode and the drain electrode respectively form Schottky contacts with the semiconductor layer.

According to some embodiments of the present disclosure, in which the source electrode and the drain electrode respectively form Ohmic contacts with the semiconductor layer.

According to some embodiments of the present disclosure, a semiconductor device is provided. The semiconductor device includes a substrate, a semiconductor layer, a source electrode, a drain electrode and a gate electrode. The semiconductor layer is disposed on the substrate, in which the semiconductor layer includes a first semiconductor region, a second semiconductor region and a third semiconductor region, in which the third semiconductor region is between the first semiconductor region and the second semiconductor region. The source electrode is in direct contact with the first semiconductor region. The drain electrode is in direct contact with the second semiconductor region. The gate electrode is disposed on and in direct contact with a top surface of the third semiconductor region.

According to some embodiments of the present disclosure, in which a doping concentration of the third semiconductor region is less than a doping concentration of the first semiconductor region and a doping concentration of second semiconductor region.

According to some embodiments of the present disclosure, in which a doping concentration of the third semiconductor region is higher than a doping concentration of the first semiconductor region and a doping concentration of second semiconductor region.

### BRIEF DESCRIPTION OF THE DRAWINGS

FIG. 1 is a schematic diagram of a semiconductor device in accordance with some embodiments of the present disclosure.

FIG. 2A is an operation schematic diagram of an on state of the semiconductor device in the FIG. 1 in accordance with some embodiments of the present disclosure.

FIG. 2B is an operation schematic diagram of an off state of the semiconductor device in the FIG. 1 in accordance with some embodiments of the present disclosure.

FIG. 3 is a schematic diagram of a semiconductor device in accordance with some embodiments of the present disclosure.

FIGS. 4A through 4D are stereograms of a semiconductor device at various stages of processing the semiconductor device in accordance with some embodiments of the present disclosure.

FIG. 5 is a current relationship diagram of a semiconductor device in accordance with some embodiments of the present disclosure.

### DETAILED DESCRIPTION

The embodiments of the present disclosure are discussed in detail below. However, it should be understood that the embodiments provide many applicable concepts that can be implemented in a wide variety of specific contexts. The embodiments discussed and disclosed are for illustrative purposes only and are not intended to limit the scope of the present disclosure. As used herein, the terms ‘first’, ‘second’, etc., do not specifically refer to order or sequence, but are intended only to distinguish components or operations that are described in the same technical terms.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

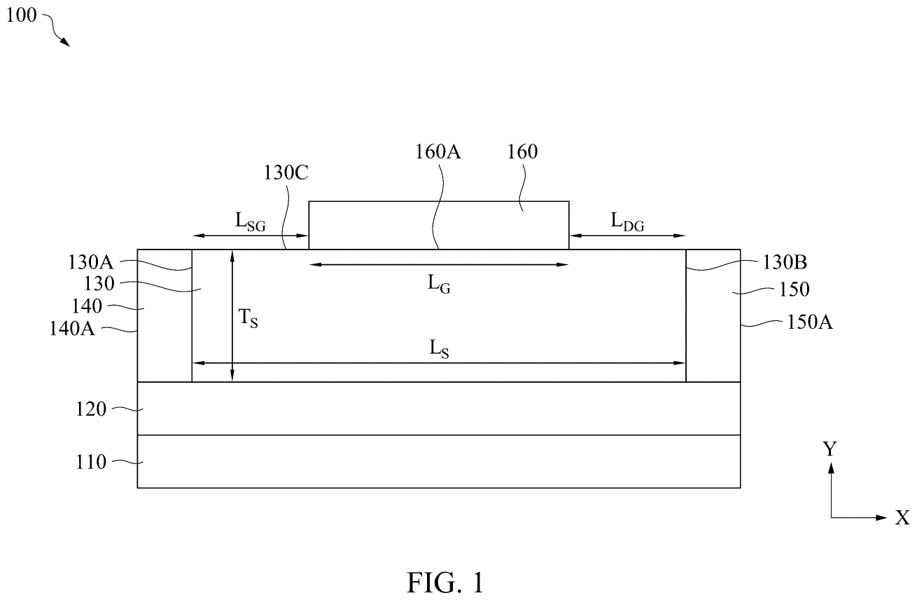

FIG. 1 is a schematic diagram of a semiconductor device 100 in accordance with some embodiments of the present disclosure. The semiconductor device 100 includes a substrate 110, an oxide layer 120, a semiconductor layer 130, a source electrode 140, a drain electrode 150 and a gate electrode 160. For illustrative purposes, a direction parallel to a direction of the gate electric field is defined as a direction Y, and a direction of a current from source electrode 140 to the drain electrode 150 is defined as a direction X, in which the direction X is perpendicular to the direction Y. The substrate 110 may be any appropriate substrate. For example, in some embodiments, the substrate 110 may be silicon (Si), silicon carbide (SiC) or high electron mobility materials. In some embodiments, the oxide layer 120 may be selectively disposed on the substrate 110. For example, in the present embodiment, the oxide layer 120 may be silicon dioxide (SiO₂). It should be noticed that the oxide layer 120 may adopt any appropriate materials without such limitation.

In some embodiments, the semiconductor layer 130 may be disposed on the substrate 110 and the oxide layer 120. The semiconductor layer 130 may be any appropriate semiconductor layer. For example, in some embodiments, the semiconductor layer 130 may be silicon, germanium, oxide semiconductor, III-V material, II-VI material or combination thereof. Furthermore, the semiconductor layer 130 may adopt any appropriate doping method to dope into different conductive types. For example, in the present embodiment, the semiconductor layer 130 may adopt an in-situ doping method to be a n type bulk semiconductor, and the body of the semiconductor layer 130 needs to be only doped once or the semiconductor layer 130 may be purchased semiconductor materials that are already doped. The design causes the semiconductor layer 130 to be fabricated without any steps in the ion implantation process, so that the design may greatly reduce steps required for the process and heat cost (e.g., the annealing process), thus making the semiconductor device 100 have advantages of reducing steps of the process, lowering the number of uses of the mask, lowering the thermal budget, avoiding the issue of misaligning and lowering the process cost.

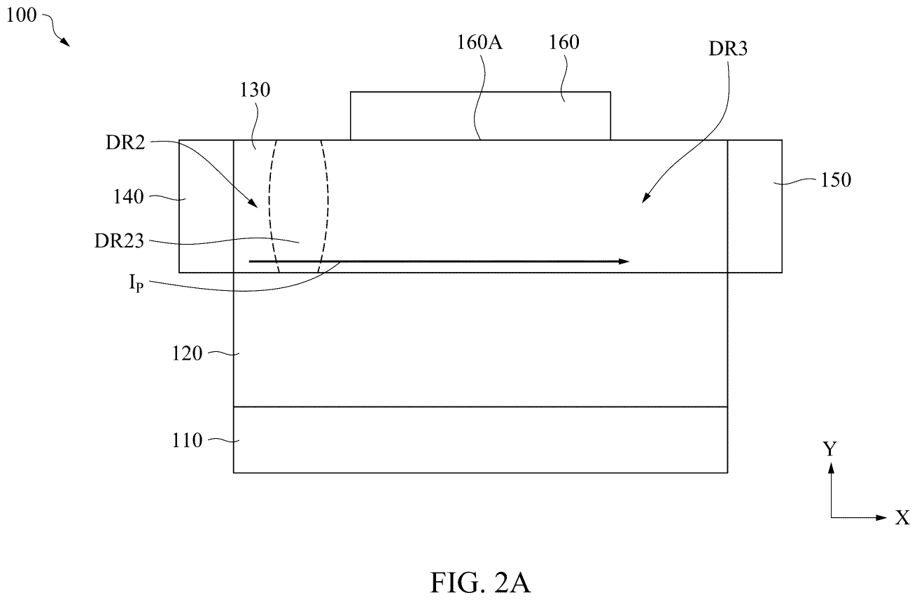

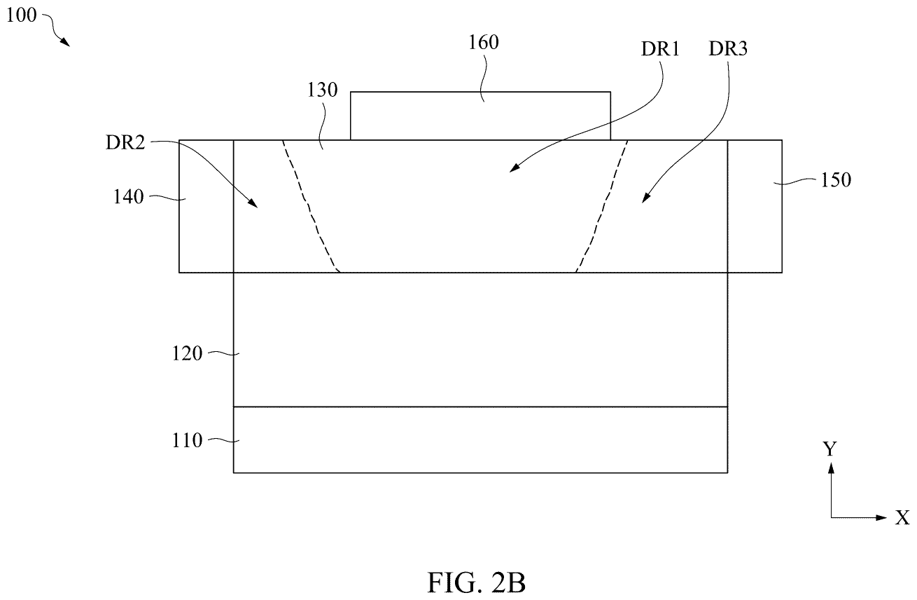

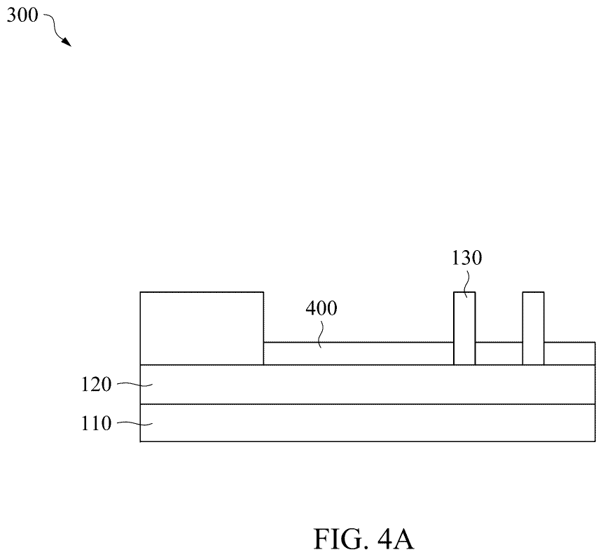

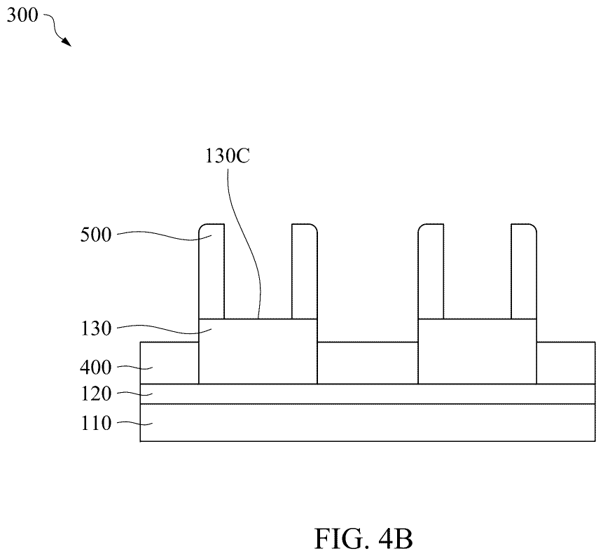

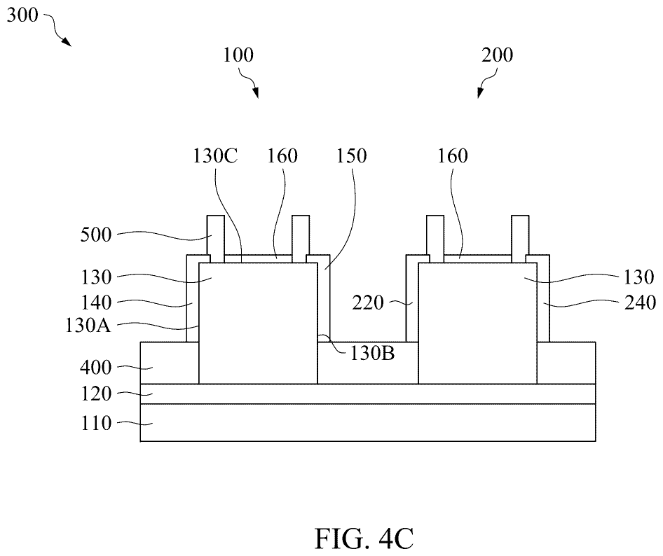

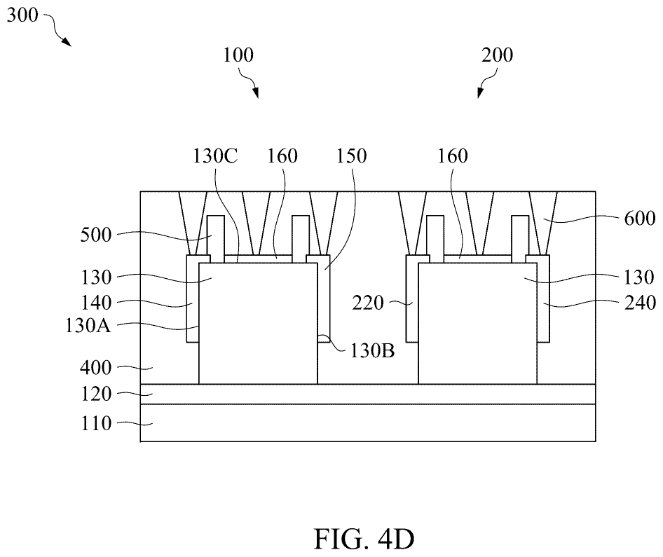

In some embodiments, the source electrode 140 may include any appropriate conductive materials. For example, in the present embodiment, the source electrode 140 may include palladium (Pd). In some embodiments, the source electrode 140 may include platinum (Pt), rhodium (Rh), nickel (Ni), ruthenium (Ru), iridium (Ir), osmium (Os), similar metals or combination thereof. Therefore, the source electrode 140 may form Schottky contacts with different Schottky barrier heights with the semiconductor layer 130 to control the size of the depletion region DR2 induced by the source electrode 140 (referring to the following FIGS. 2A and 2B), in which the size of the depletion region DR2 is positively correlated with the Schottky barrier height (i.e., the Schottky barrier height is higher, and the size of the depletion region DR2 is larger), and the size of the depletion region DR2 is related to the voltage applied on the source electrode 140 (i.e., the positive bias voltage shrinks the size of the depletion region DR2, and the negative bias voltage enlarges the size of the depletion region DR2). In addition, the source electrode 140 may be disposed in different positions according to functional requirements. For example, in the present embodiment, the source electrode 140 is disposed on the surface 130A of the semiconductor layer 130 along the direction X. In some embodiments, an endpoint of the source electrode 140 may surround the semiconductor layer 130 (e.g., an endpoint, the surface 130A, the surface 130B or the surface 130C of the semiconductor layer 130), and be bonded at the tail end of the semiconductor layer 130. For example, the source electrode 140 may be in direct contact with the surface 130A of the semiconductor layer 130 and the surface 130C of the semiconductor layer 130 (referring to FIG. 4D). The source electrode 140 has a surface 140A being in direct contact with the surface 130A of the semiconductor layer 130, in which the source electrode 140 overlaps the surface 130A of the semiconductor layer 130 along a direction perpendicular to the surface 140A of the source electrode 140. Therefore, this design may reduce the resistances of the junctions (e.g., the surfaces 130A and 140A) of the source electrode 140 and the semiconductor layer 130, and enlarger the depletion region DR2 induced by the source electrode 140 (referring to the following FIGS. 2A and 2B).

In some embodiments, the drain electrode 150 may include any appropriate conductive materials. For example, in the present embodiment, the drain electrode 150 may include Pd, Pt, Rh, Ni, Ru, Ir, Os, similar metals or combination thereof. In the present embodiment, the drain electrode 150 may include the same materials as the source electrode 140 (e.g., Pd, Pt, Ni, Rh, Ru, Ir, Os). In some other embodiments, the drain electrode 150 may include materials different from the source electrode 140. Therefore, the drain electrode 150 may form Schottky contacts with different Schottky barrier heights with the semiconductor layer 130 to control the size of the depletion region DR3 induced by the drain electrode 150 (referring to the following FIGS. 2A and 2B), in which the size of the depletion region DR3 is positively correlated with the Schottky barrier height (i.e., the Schottky barrier height is higher, and the size of the depletion region DR3 is larger), and the size of the depletion region DR3 is related to the voltage applied on the drain electrode 150 (i.e., the positive bias voltage shrinks the size of the depletion region DR3, and the negative bias voltage enlarges the size of the depletion region DR3). In addition, the drain electrode 150 may be disposed in different positions according to functional requirements. For example, in the present embodiment, the drain electrode 150 is disposed on the surface 130B of the semiconductor layer 130 opposite to the surface 130A along the direction X. In the present embodiment, an endpoint of the drain electrode 150 may surround the semiconductor layer 130 (e.g., an endpoint, the surface 130A, the surface 130B of the semiconductor layer 130), and be bonded at the tail end of the semiconductor layer 130. For example, in some embodiments, the drain electrode 150 may be in direct contact with the surface 130B of the semiconductor layer 130 and the surface 130C of the semiconductor layer 130 (referring to FIG. 4D). The drain electrode 150 has a surface 150A, thus being in direct contact with the surface 130B of the semiconductor layer 130, in which the drain electrode 150 overlaps the surface 130B of the semiconductor layer 130 along a direction perpendicular to the surface 150A of the drain electrode 150. Therefore, this design may reduce the resistances of the junctions (e.g., the surfaces 130B and 150A) of the drain electrode 150 and the semiconductor layer 130, and enlarger the depletion region DR3 induced by the drain electrode 150 (referring to the following FIGS. 2A and 2B).

In some embodiments, the gate electrode 160 may include any appropriate conductive materials. For example, in the present embodiment, the gate electrode 160 may include Pd, Ni, Pt, Rh, Ru, Ir, Os, similar metals or combination thereof. In the present embodiment, the gate electrode 160 may include the same materials as the source electrode 140 and the drain electrode 150 (e.g., Ni or Pd). In some embodiments, the gate electrode 160 may include materials different from the source electrode 140 and the drain electrode 150. Therefore, the gate electrode 160 may form Schottky contacts with different Schottky barrier heights with the semiconductor layer 130 to control the size of the depletion region DR1 induced by the gate electrode 160 (referring to the following FIG. 2B), in which the size of the depletion region DR1 (referring to the following FIG. 2B) is positively correlated with the Schottky barrier height (i.e., the Schottky barrier height is higher, and the size of the depletion region DR1 (referring to the following FIG. 2B) is larger), and the size of the depletion region DR1 (referring to the following FIG. 2B) is related to the voltage applied on the gate electrode 160 (i.e., the positive bias voltage shrinks the size of the depletion region DR1 (referring to the following FIG. 2B), and the negative bias voltage enlarges the size of the depletion region DR1 (referring to the following FIG. 2B)). In addition, the gate electrode 160 may be disposed in different positions according to functional requirements. For example, in the present embodiment, the gate electrode 160 is disposed on the surface 130C of the semiconductor layer 130 along the direction Y. In detail, the gate electrode 160 is between the source electrode 140 and the drain electrode 150, and the gate electrode 160 has a surface 160A, thus being in direct contact with the surface 130C of the semiconductor layer 130. Therefore, this design may reduce the resistances of the junctions (e.g., the surfaces 130C and 160A) of the gate electrode 160 and the semiconductor layer 130, and enlarger the depletion region DR1 induced by the gate electrode 160 (referring to the following FIG. 2B).

The Schottky barrier heights of the gate electrode 160, the source electrode 140 and the drain electrode 150 may be adjusted according to the functional requirements. For example, in the present embodiment, the Schottky barrier height between the gate electrode 160 and the semiconductor layer 130 is less than the Schottky barrier height between the source electrode 140 and the semiconductor layer 130 and the Schottky barrier height between the drain electrode 150 and the semiconductor layer 130 by designing the metal material of the gate electrode 160 differently from the metal materials of the source electrode 140 and the drain electrode 150.

In some embodiments, the gate electrode 160 may be spaced apart from the source electrode 140 and the drain electrode 150. In detail, in the present embodiment, the gate electrode 160 and the source electrode 140 are spaced apart by a length L_{SG}. The gate electrode 160 and the drain electrode 150 are spaced apart by a length L_{DG}. A length L_{G} of the gate electrode 160 is larger than the length L_{SG} between the gate electrode 160 and the source electrode 140, and the length L_{G} of the gate electrode 160 is larger than the length L_{DG} between the gate electrode 160 and the drain electrode 150. In the present embodiment, the length L_{SG} is the same as the length L_{DG}. In some other embodiments, the length L_{SG} may be different from the length L_{DG}.

In some embodiments, one or more layers of spacer layers (not shown) are selectively disposed between the source electrode 140 and the semiconductor layer 130. For example, in some embodiments, the spacer layer (not shown) may include a nanoparticle, a semiconductor oxide or a nitride to improve the performance of the semiconductor device 100. In another embodiment, the spacer layer (not shown) may be a van der Waals force layer between the semiconductor layer 130 and the gate electrode 160 to improve the performance of the semiconductor device 100.

In some embodiments, one or more layers of spacer layers (not shown) are selectively disposed between the drain electrode 150 and the semiconductor layer 130. For example, in some embodiments, the spacer layer (not shown) may include a nanoparticle, a semiconductor oxide or a nitride to improve the performance of the semiconductor device 100. In another embodiment, the spacer layer (not shown) may be a van der Waals force layer between the semiconductor layer 130 and the drain electrode 150 to improve the performance of the semiconductor device 100.

In some embodiments, one or more layers of dielectric buffer layers (not shown) are selectively disposed between the gate electrode 160 and the semiconductor layer 130. For example, in some embodiments, the dielectric buffer layer (not shown) may include a nanoparticle, a semiconductor oxide or a nitride to improve the performance of the semiconductor device 100. In another embodiment, the dielectric buffer layer (not shown) may be a van der Waals force layer between the semiconductor layer 130 and the gate electrode 160 to improve the performance of the semiconductor device 100.

FIG. 2A is an operation schematic diagram of an on state of the semiconductor device 100 in the FIG. 1. First, a negative bias is applied to the gate electrode 160, and the depletion region DR1 (referring to FIG. 2B) induced by the gate electrode 160 gradually shrinks in the directions X and Y, so that the depletion region DR2 (referring to FIG. 2B) induced by the source electrode 140 gradually enlargers toward the drain electrode 150, and the depletion region DR3 (referring to FIG. 2B) induced by the drain electrode 150 gradually enlargers toward the source electrode 140. Following, the depletion region DR2 (referring to FIG. 2B) induced by the source electrode 140 may be in contact with and connected to (e.g., overlapping) the depletion region DR3 (referring to FIG. 2B) induced by the drain electrode 150 to form a long depletion region DR23 after continuously applying the negative bias to the gate electrode 160 for a period of time, in which the gate voltage (V_{G}) of the gate electrode 160 is less than the flat-band voltage (V_{FB}). The punch through effect may happen in the depletion region DR23, thus producing a punch through current flowing from the source electrode 140 to the drain electrode 150 through the depletion region DR23. Furthermore, the Schottky barrier height of the gate electrode 160 may be less than the Schottky barrier heights of the source electrode 140 and the drain electrode, so that the depletion region DR1 is smaller (referring to FIG. 2B) (for example, the thickness of the depletion region DR1 in the direction Y), and the depletion regions DR2 and DR3 are larger (referring to FIG. 2B) (for example, the thicknesses of the depletion regions DR2 and DR3 in the direction X) to achieve the better performance of the semiconductor device 100. Therefore, a smaller negative bias is applied to the gate electrode 160 of the semiconductor device 100 to easily make the depletion region DR2 (referring to FIG. 2B) induced by the source electrode 140 be in contact with (e.g., overlapping) the depletion region DR3 (referring to FIG. 2B) induced by the drain electrode 150, which in turn produces the punch through effect when the semiconductor device 100 is turned on as labeled in the punch through current Iₚ. In addition, the semiconductor device 100 may have similar properties to those of the p type metal semiconductor (pMES) without adjusting the component size of the semiconductor device 100 by the punch through effect. Thus, the wiring and process costs of the semiconductor device 100 may be reduced.

FIG. 2B is an operation schematic diagram of an off state of the semiconductor device 100 in the FIG. 1 in accordance with some embodiments of the present disclosure. First, a positive bias is applied to the gate electrode 160, and the depletion region DR1 induced by the gate electrode 160 gradually enlargers in the directions X and Y. Thus, the depletion region DR2 induced by the source electrode 140 gradually shrinks toward the source electrode 140, and the depletion region DR3 induced by the drain electrode 150 gradually shrinks toward the drain electrode 150. Following, the positive bias of the gate electrode 160 is larger than a pinch-off voltage, such that the depletion region DR1 induced by the gate electrode 160 spaces the depletion region DR2 induced by the source electrode 140 apart from the depletion region DR3 induced by the drain electrode 150, thus turning off the semiconductor device 100. At this point, the drain current is primarily composed of leakage current, with no remaining punch-through component.

In addition, the contact between the depletion regions DR2 and DR3 may be controlled by changing a length L_{S} (referring to FIG. 1) and a thickness T_{S} (referring to FIG. 1) of the semiconductor layer 130. For example, in some embodiments, the length L_{S} (referring to FIG. 1) of the semiconductor layer 130 may be shorten, so that the depletion region DR2 may be easily in contact with the depletion region DR3, and the ION current may be increased. In design, it should be noted that the length L_{S} (referring to FIG. 1) of the semiconductor layer 130 should not be too short to avoid increasing the leakage current of the semiconductor layer 130. In addition, the thickness T_{S} (referring to FIG. 1) of the semiconductor layer 130 may be increased to increase the ION current and the Ioff current. Therefore, in design, it should be noted that the thickness T_{S} (referring to FIG. 1) of the semiconductor layer 130 should not be too large. The excessive thickness T_{S} may make the depletion region DR1 hardly spaces the depletion region DR2 apart from the depletion region DR3, thus increasing the sub-threshold swing of the semiconductor device 100 (for example, an on-off speed or a sensitivity of the semiconductor device 100 decrease), and a higher positive bias is needed to apply to the gate electrode 160 to turn off the semiconductor device 100 for operation.

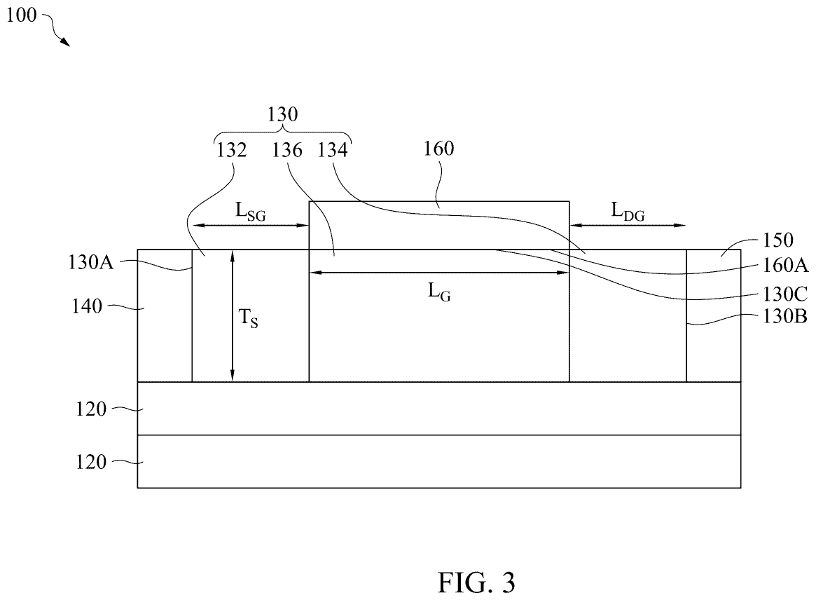

FIG. 3 is a schematic diagram of a semiconductor device 100 in accordance with some embodiments of the present disclosure. The present embodiment is similar to the embodiment of FIG. 1 described above. FIG. 3 differs from FIG. 1 in that: the semiconductor layer 130 includes regions 132, 134 and 136. The region 132 is adjacent to the source electrode 140. The region 134 is adjacent to the drain electrode 150. The region 136 is between the region 132 and 134, and the gate electrode 160 overlaps the region 136 along a direction (i.e., the direction Y) perpendicular to a surface 160A of the gate electrode 160. The regions 132, 134 and 136 may be formed by any appropriate doping method. The regions 132 and 134 may be formed by an ion implantation method or a deposition method. The region 136 may be formed by an in situ doping method. Furthermore, doping concentrations and conductive types of the regions 132, 134 and 136 may be adjusted according to the functional requirements. For example, in some embodiments, the regions 132 and 134 may have the same conductive type, and the conductive type of the regions 132 and 134 may be different from the region 136. For example, the region 136 may be an N type semiconductor. The regions 132 and 134 may be a P type semiconductor. In some embodiments, the doping concentrations of the regions 132 and 134 are higher than the doping concentration of the region 136. The regions 132 and 134 with higher doping concentration may be served as a buffer layer of the semiconductor device 100 to improve the stability of the semiconductor device 100. In another embodiment, the doping concentrations of the regions 132 and 134 are less than the doping concentration of the region 136 to form an Ohmic contact between the source electrode 140 and the drain electrode 150. Therefore, the region 136 with high doping concentration of the semiconductor device 100 may have the lager punch through current IP.

FIGS. 4A through 4D are stereograms of a semiconductor device 300 at various stages of processing the semiconductor device 300 in accordance with some embodiments of the present disclosure. In the present embodiment, the semiconductor device 300 may include the semiconductor device 100 and a semiconductor device 200 to form a complementary metal semiconductor (CMES), in which the semiconductor device 100 is the PTnMES, and the semiconductor device 200 is the nMES.

Refer to FIG. 4A. The semiconductor layer 130 is formed on the substrate 110 and the oxide layer 120. For example, in the present embodiment, an oxide layer 400 is formed on the oxide layer 120. Following, an etching process is performed to the oxide layer 400 to form a trench. Following, the semiconductor layer 130 is formed in the trench. For example, in the present embodiment, the semiconductor layer 130 may be formed by a sidewall image transfer (SIT) process.

Following, refer to the FIG. 4B. A spacer layer 500 is formed on the surface 130C of the semiconductor layer 130, in which the spacer layer 500 may be a nitride, such as silicon nitride (SiN). For example, in the present embodiment, a hard mask (not shown) is formed on the surface 130C of the semiconductor layer 130. Following, a photolithography process is performed to the hard mask to form an opening on the surface 130C of the semiconductor layer 130, and expose the surface 130C of the semiconductor layer 130, in which the photolithography process may include exposure, developing, baking, similar steps or combined steps thereof. Following, the spacer layer 500 is deposited on the exposed surface 130C of the semiconductor layer 130. Following, part of the spacer layer 500 is removed.

Refer to the FIG. 4C. A metal electrode layer is formed on the semiconductor layer 130 by using a chemical vapor deposition (CVD) and so on. Following, regions of the gate electrode 160, the source electrode 140 and the drain electrode 150 are defined by a mask. Following, part of the metal electrode layer is removed by an etching process and so on to form the gate electrode 160, the source electrode 140 and the drain electrode 150, in which the spacer layer 500 spaced apart the gate electrode 160, the source electrode 140 and the drain electrode 150. In the present embodiment, endpoints of the source electrode 140 and the drain electrode 150 may surround the semiconductor layer 130 (e.g., an endpoint, the surface 130A, the surface 130B or the surface 130C of the semiconductor layer 130), and be bonded at the tail end of the semiconductor layer 130 (for example, the source electrode 140 and the drain electrode 150 may be in direct contact with the surface 130A of the semiconductor layer 130 and the surface 130C of the semiconductor layer 130).

In addition, in the present embodiment, the gate electrode 160, the source electrode 140 and the drain electrode 150 may be formed by patterning a same metal electrode layer, so that the gate electrode 160, the source electrode 140 and the drain electrode 150 may have a same material. In some other embodiments, a first metal electrode layer is deposited and patterned to form the gate electrode 160, and a second metal electrode layer is deposited and patterned to form the source electrode 140 and the drain electrode 150, so that the gate electrode 160 may have a metal material different from those of the source electrode 140 and the drain electrode 150. Thus, two gate electrodes 160 respectively form Schottky contacts with two fin semiconductor layers 130. In the present embodiment, the source electrode 140 and the drain electrode 150 respectively form Schottky contacts with fin semiconductor layers 130, so that the semiconductor device 100 having a gate Schottky contact and source/drain Schottky contacts is formed. Following, a source electrode 220 and a drain electrode 240 are formed on the both sides of another fin semiconductor layer 130 by using CVD, deposition, PVD and so on. In the present embodiment, the source electrode 220 and the drain electrode 240 may have materials different from those of the source electrode 140 and the drain electrode 150 (e.g., Titanium (Ti)), in which in the present embodiment, endpoints of the source electrode 220 and the drain electrode 240 may surround the semiconductor layer 130 (e.g., an endpoint, the surface 130A, the surface 130B or the surface 130C of the semiconductor layer 130), and be bonded at the tail end of the semiconductor layer 130 (for example, the source electrode 220 and the drain electrode 240 may be in direct contact with the surface 130A of the semiconductor layer 130 and the surface 130C of the semiconductor layer 130). Thus, the source electrode 220 and the drain electrode 240 respectively form Ohmic contacts with fin semiconductor layers 130, so that the semiconductor device 200 having a gate Schottky contact and source/drain Ohmic contacts is formed. Following, refer to FIG. 4D. A back end of line (BEOL) is performed to form a drain/source contact 600. In some embodiments, the drain/source contact 600 may be a metal wire, in which the drain/source contact 600 is electrically connected to the gate electrode 160, the source electrode 140, the drain electrode 150, the source electrode 220 and the drain electrode 240. In addition, in some embodiments, a chemical mechanical polishing (CMP) process is performed to the semiconductor device 300 after forming the drain/source contact 600.

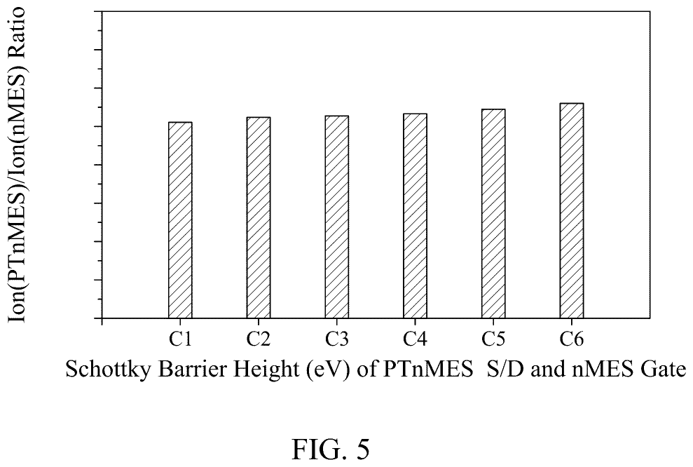

FIG. 5 is a current relationship diagram of a semiconductor device 300 in accordance with some embodiments of the present disclosure. In FIG. 5, a ratio of the ION current (ION (PTnMES)/ION (nMES) of the semiconductor devices 100 and 200 are respectively tested, in which the horizontal axis is the Schottky barrier heights of the source electrode 140 and the drain electrode 150 of the semiconductor device 100 and the gate electrode 160 of the semiconductor device 200. In the present embodiment, the Schottky barrier heights, in ascending order, are a condition C1, a condition C2, a condition C3, a condition C4, a condition C5 and a condition C6. As can be seen from FIG. 5, the ratio of the ION current (ION (PTnMES)/ION (nMES) increases in ascending order when the semiconductor device 300 is operated under conditions C1, C2, C3, C4, C5 and C6, and reaches the maximum value at the condition C6. The current under the condition C6 of the semiconductor device 100 of the semiconductor device 300 exceeds that of the semiconductor device 200 of the semiconductor device 300. In other word, the semiconductor device 100 merely adjusts the Schottky barrier, so that the semiconductor device 100 may have a larger current without adjusting the size of the semiconductor device 100, thus replacing the conventional pMES of the CMES.

According to some embodiments of the present disclosure, a semiconductor device is provided. The semiconductor device may be a signal carrier device without doping by designing the semiconductor device as punch-through nMES (PTnMES) and designing source and drain electrodes of the semiconductor device as Schottky contacts. Furthermore, by adjusting the Schottky barrier between the source and drain electrodes, the semiconductor device may have current properties similar to those of the pMES without increasing the size. By matching the carrier mobilities of the nMES and the PTnMES, the semiconductor device may have great carrier mobility, thus increasing the performance of the CMES. Therefore, the semiconductor device may have great reliability and stability in applications for the RF and the microwave circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a semiconductor layer disposed on the substrate;
a source electrode in direct contact with the semiconductor layer;
a drain electrode in direct contact with the semiconductor layer; and
a gate electrode between the source electrode and the drain electrode, wherein the gate electrode is in direct contact with semiconductor layer.

2. The semiconductor device of claim 1, wherein the gate electrode and the semiconductor layer form a Schottky contact.

3. The semiconductor device of claim 1, wherein a Schottky barrier height between the gate electrode and the semiconductor layer is less than a Schottky barrier height between the source electrode and the semiconductor layer and a Schottky barrier height between the drain electrode and the semiconductor layer.

4. The semiconductor device of claim 1, wherein the semiconductor layer comprises:
a first semiconductor region adjacent to the source electrode;
a second semiconductor region adjacent to the drain electrode; and
a third semiconductor region between the first semiconductor region and the second semiconductor region, wherein doping concentrations of the first and second semiconductor regions are higher than a doping concentration of the third semiconductor region.

5. The semiconductor device of claim 4, wherein the first semiconductor region and the second semiconductor region have a same conductive type.

6. The semiconductor device of claim 4, wherein the gate electrode overlaps the third semiconductor region along a direction perpendicular to a surface of the gate electrode.

7. The semiconductor device of claim 1, further comprising a spacer layer separating the source electrode or the drain electrode from the semiconductor layer, wherein the spacer layer comprises a nanoparticle, a semiconductor oxide or a nitride.

8. The semiconductor device of claim 1, further comprising a dielectric buffer layer between the semiconductor layer and the gate electrode, wherein the dielectric buffer layer comprises a nanoparticle, a semiconductor oxide or a nitride.

9. The semiconductor device of claim 1, wherein the gate electrode, the source electrode and the drain electrode have the same material.

10. The semiconductor device of claim 1, wherein a material of the gate electrode is different from a material of the source electrode and a material of the drain electrode.

11. The semiconductor device of claim 1, wherein the source electrode and the drain electrode respectively form Schottky contacts with the semiconductor layer.

12. The semiconductor device of claim 1, wherein the source electrode and the drain electrode respectively form Ohmic contacts with the semiconductor layer.

13. A semiconductor device, comprising:
a substrate;
a semiconductor layer disposed on the substrate, wherein the semiconductor layer comprises a first semiconductor region, a second semiconductor region and a third semiconductor region, wherein the third semiconductor region is between the first semiconductor region and the second semiconductor region;
a source electrode in direct contact with the first semiconductor region;
a drain electrode in direct contact with the second semiconductor region; and
a gate electrode disposed on and in direct contact with a top surface of the third semiconductor region.

14. The semiconductor device of claim 13, wherein a doping concentration of the third semiconductor region is less than a doping concentration of the first semiconductor region and a doping concentration of second semiconductor region.

15. The semiconductor device of claim 13, wherein a doping concentration of the third semiconductor region is higher than a doping concentration of the first semiconductor region and a doping concentration of second semiconductor region.
